(19) United States
(12) Patent Application Publication
(10) Pub. No.: US 2025/0239439 A1
(43) Pub. Date: Jul. 24, 2025

(54) EDGE RING AND SUBSTRATE PROCESSING APPARATUS INCLUDING THE SAME

(71) Applicant: Samsung Electronics Co., Ltd., Suwon-si (KR)

(72) Inventors: Jaebin KIM, Suwon-si (KR); JAESUNG KIM, Suwon-si (KR); Seongjun DOH, Suwon-si (KR); Jong In PARK, Suwon-si (KR); SANG-HO LEE, Suwon-si (KR); KANGMIN JEON, Suwon-si (KR); HAEYOON CHOI, Suwon-si (KR); Jaewon HEO, Suwon-si (KR); SANGMOK LEE, Suwon-si (KR); SEUNGHWAN LEE, Suwon-si (KR)

(21) Appl. No.: 18/786,129

(22) Filed: Jul. 26, 2024

(30) Foreign Application Priority Data
Jan. 19, 2024 (KR) 10-2024-0008850

(51) Int. Cl. H01J 37/32

(52) U.S. Cl. CPC H01J 37/32642; H01J 2237/3321; H01J 2237/334

(57) ABSTRACT

An edge ring includes a first edge ring region having a first curvature center; and a second edge ring region connected to the first edge ring region and having a second curvature center. The first edge ring region and the second edge ring region are arranged on a horizontal plane. The first curvature center and the second curvature center are the same as each other. A first vertical axis is perpendicular to the horizontal plane and passes through the second curvature center of the second edge ring region. The first edge ring region includes a first inclined surface intersecting the horizontal plane. The second edge ring region includes a second inclined surface intersecting the horizontal plane. A first horizontal distance from the first vertical axis to the first inclined surface is greater than a second horizontal distance from the first vertical axis to the second inclined surface.

### CROSS-REFERENCE TO RELATED APPLICATION

This U.S. nonprovisional application claims priority under 35 U.S.C § 119 to Korean Patent Application No. 10-2024-0008850 filed on Jan. 19, 2024 in the Korean Intellectual Property Office, the disclosure of which is hereby incorporated by reference in its entirety.

### BACKGROUND

The present inventive concepts relate to an edge ring and a substrate processing apparatus including the same, and more particularly, to an edge ring in which an irregular distance is provided from a central axis to an inclined surface at a certain height and a substrate processing apparatus including the same.

Semiconductor devices may be fabricated through various processes. In processes such as etching and deposition which are performed on a substrate in fabricating semiconductor devices, plasma including radicals and ions are generated. A non-uniform density of the plasma on the substrate may have cause non-uniform physical features and/or electrical properties of semiconductor devices, which may lead to a low fabrication yield of the semiconductor devices. To control a concentration of the plasma, an edge ring may be used which surrounds a chuck body that supports the substrate.

### SUMMARY

Some embodiments of the present inventive concepts provide an edge ring capable of increasing a region where plasma is uniformly present and a substrate processing apparatus including the same.

Some embodiments of the present inventive concepts provide an edge ring capable of increasing an etch rate of a substrate edge region by controlling a concentration of plasma and a substrate processing apparatus including the same.

Some embodiments of the present inventive concepts provide an edge ring capable of increasing an etch rate of a substrate edge region by decreasing a plasma sheath region and a substrate processing apparatus including the same.

Some embodiments of the present inventive concepts provide an edge ring capable of decreasing the degree of asymmetry in an amount of etching in accordance with a pattern direction of a substrate and a substrate processing apparatus including the same.

The object of the present inventive concepts is not limited to the mentioned above, and other objects which have not been mentioned above will be clearly understood to those skilled in the art from the following description.

According to an aspect of the present disclosure, an edge ring includes a first edge ring region that has a first arc shape having a first curvature center; and a second edge ring region connected to the first edge ring region and having a second arc shape having a second curvature center. The first edge ring region and the second edge ring region are arranged on a horizontal plane. The first curvature center and the second curvature center are the same as each other. A first vertical axis is perpendicular to the horizontal plane and passes through the second curvature center of the second edge ring region and the first curvature center of the first edge ring region. The first edge ring region includes a 1-1st edge ring region having a first inclined surface intersecting the horizontal plane. The second edge ring region includes a 2-1st edge ring region having a second inclined surface intersecting the horizontal plane. A first horizontal distance from the first vertical axis to the first inclined surface is greater than a second horizontal distance from the first vertical axis to the second inclined surface.

According to an aspect of the present disclosure, an edge ring includes an inner top surface parallel to a horizontal plane, an outer top surface that is parallel to the horizontal plane and surrounds the inner top surface, and an inclined surface that intersects the horizontal plane and connects the inner top surface to the outer top surface. The outer top surface is at a level higher than a level of the inner top surface in a vertical direction perpendicular to the horizontal plane. A lower end of the inclined surface is at a level which is the same as the level of the inner top surface in the vertical direction. An upper end of the inclined surface is at a level which is the same as the level of the outer top surface in the vertical direction. A first horizontal distance between a first portion of the inclined surface and a vertical axis of the edge ring at a first level in the vertical direction is different from a second horizontal distance between a second portion of the inclined surface and the vertical axis of the edge ring at the first level. The vertical axis extends in the vertical direction and passes a center of the edge ring.

According to an aspect of the present disclosure, a substrate processing apparatus includes a process chamber that provides a process space, a stage disposed in the process space and supporting a substrate, and a showerhead disposed in the process space and disposed above the stage in a vertical direction perpendicular to an upper surface of the stage. The stage includes a chuck that supports the substrate, and an edge ring that surrounds the chuck. The edge ring includes a first edge ring region that has a first arc shape having a first curvature center, and a second edge ring region connected to the first edge ring region and having a second arc shape having a second curvature center. The first curvature center and the second curvature center are the same as each other. A first vertical axis is perpendicular to an upper surface of the chuck and passes through the second curvature center of the second edge ring region and the first curvature center of the first edge ring region. The upper surface of the chuck corresponds to the upper surface of the stage. The first edge ring region and the second edge ring region have a first inclined surface intersecting a horizontal plane parallel to the upper surface of the chuck and a second inclined surface intersecting the horizontal plane, respectively. A first horizontal distance from the first vertical axis to the first inclined surface at a first level in the vertical direction is greater than a second horizontal distance from the first vertical axis to the second inclined surface at the first level.

Details of other example embodiments are included in the description and drawings.

### BRIEF DESCRIPTION OF DRAWINGS

FIG. 1 illustrates a diagram showing a substrate processing apparatus according to some embodiments of the present inventive concepts.

FIG. 2 illustrates an enlarged diagram showing section X of a substrate processing apparatus according to some embodiments of the present inventive concepts.

FIG. 3 illustrates an enlarged diagram showing section Y of a substrate processing apparatus according to some embodiments of the present inventive concepts.

FIG. 4 illustrates a perspective view showing an edge ring according to some embodiments of the present inventive concepts.

FIG. 5 illustrates a plan view showing an edge ring according to some embodiments of the present inventive concepts.

FIG. 6 illustrates a perspective view showing a first edge ring region according to some embodiments of the present inventive concepts.

FIG. 7 illustrates a cross-sectional view showing a first edge ring region according to some embodiments of the present inventive concepts.

FIG. 8 illustrates an exploded perspective view showing a first edge ring region according to some embodiments of the present inventive concepts.

FIG. 9 illustrates a perspective view showing a second edge ring region according to some embodiments of the present inventive concepts.

FIG. 10 illustrates a cross-sectional view showing a second edge ring region according to some embodiments of the present inventive concepts.

FIG. 11 illustrates an exploded perspective view showing a second edge ring region according to some embodiments of the present inventive concepts.

FIG. 12 illustrates a perspective view showing a first connection part according to some embodiments of the present inventive concepts.

FIG. 13 illustrates a plan view showing an edge ring according to some embodiments of the present inventive concepts.

### DETAILED DESCRIPTION OF EMBODIMENTS

The following will now describe some embodiments of the present inventive concepts with reference to the accompanying drawings. Like reference numerals may indicate like components throughout the description.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called an upward direction, and a direction opposite to the first direction D1 may be called a downward direction. The first direction D1 and its opposite direction may be called a vertical direction. In addition, each of the second direction D2 and the third direction D3 may be called a horizontal direction.

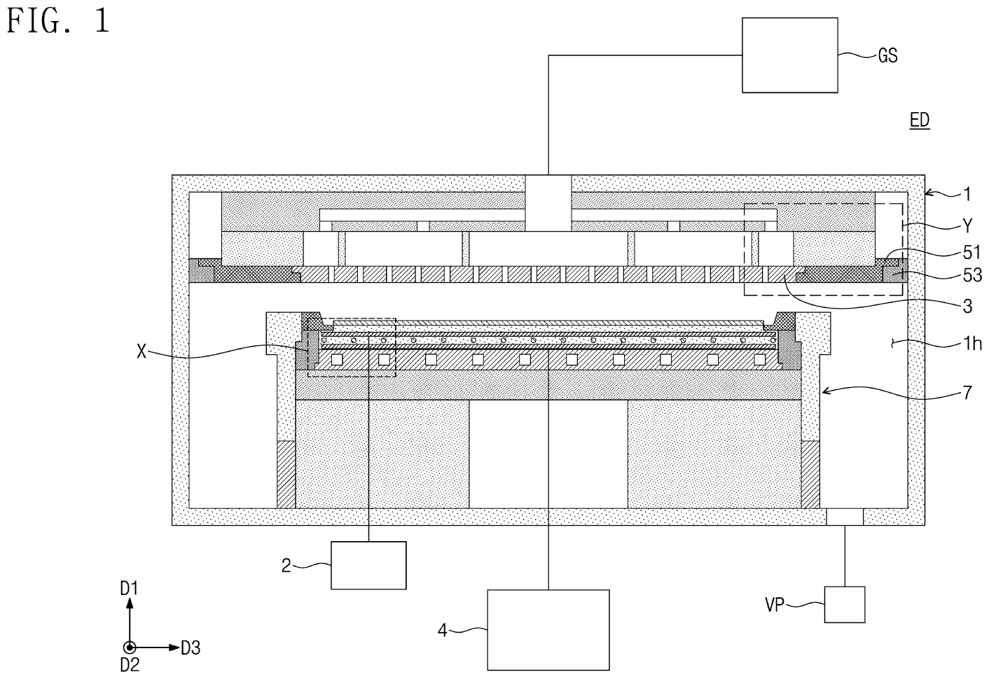

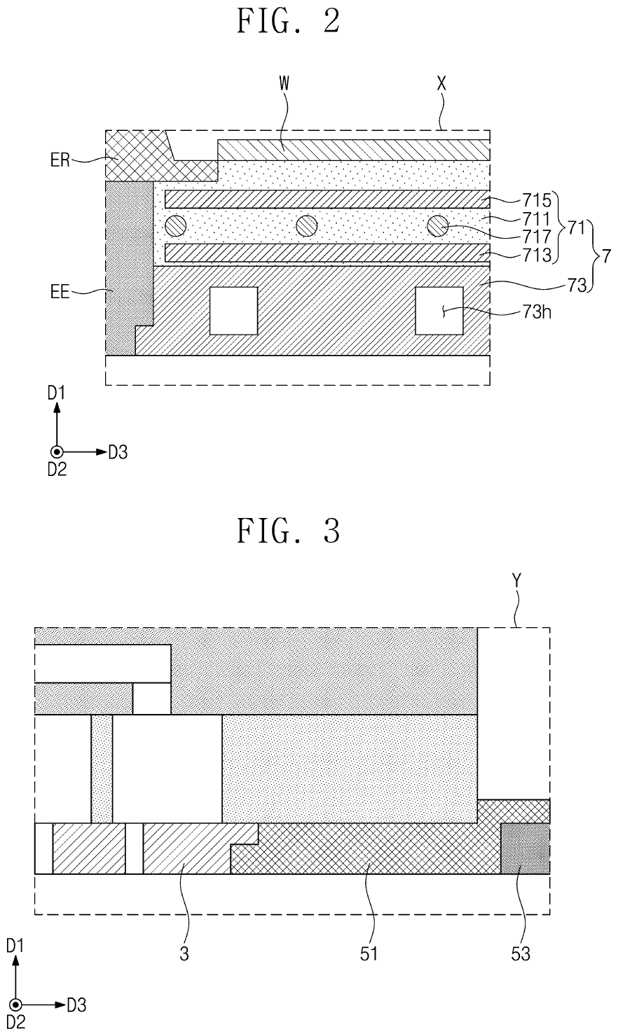

FIG. 1 illustrates a diagram showing a substrate processing apparatus ED according to some embodiments of the present inventive concepts. FIG. 2 illustrates an enlarged diagram showing section X of the substrate processing apparatus ED of FIG. 1 according to some embodiments of the present inventive concepts. FIG. 3 illustrates an enlarged diagram showing section Y of the substrate processing apparatus ED of FIG. 1 according to some embodiments of the present inventive concepts.

Referring to FIG. 1, the substrate processing apparatus ED may be provided. The substrate processing apparatus ED may perform an etching process and/or a deposition process on a substrate W. In this description, the term “substrate” may mean a silicon (Si) wafer, but the present inventive concepts are not limited thereto. The substrate processing apparatus ED may use plasma to process the substrate W. The substrate processing apparatus ED may generate the plasma in various ways. For example, the substrate processing apparatus ED may be a capacitively coupled plasma (CCP) apparatus and/or an inductively coupled plasma (ICP) apparatus. For convenience, the following will illustrate and discuss a CCP type substrate processing apparatus. The substrate processing apparatus ED may include a process chamber 1, a stage 7, a showerhead 3, an outer ring 51, a heating liner ring 53, a direct-current (DC) power generator 2, a radio-frequency (RF) power generator 4, a vacuum pump VP, and a gas supply GS.

The process chamber 1 may provide a process space 1h. A process of the substrate W may be performed in the process space 1h. The process space 1h may be isolated from an external space. While a process is performed on the substrate W, the process space 1h may be in a substantially vacuum state. The process chamber 1 may have a cylindrical shape, but the present inventive concepts are not limited thereto.

The stage 7 may be positioned in the process chamber 1. For example, the stage 7 may be positioned in the process space 1h. The stage 7 may support and/or hold the substrate W. A process may be performed on the substrate W in a state where the substrate W is placed on the stage 7. The stage 7 will be further discussed in detail below.

The DC power generator 2 may apply a DC power to the stage 7. The DC power applied from the DC power generator 2 may rigidly place the substrate W on a certain position on the stage 7. For example, the DC power applied to the stage 7 may generate an electrostatic force to hold the substrate W placed on the stage 7 in place.

The RF power generator 4 may supply a RF power to the stage 7. It may thus be possible to control the plasma in the process space 1h. For example, it may be possible to adjust a concentration of the plasma and an energy of particles.

The vacuum pump VP may be connected to the process space 1h. The vacuum pump VP may apply a vacuum pressure to the process space 1h while a process is performed on the substrate W.

The gas supply GS may supply the process space 1h with gas. The gas supply GS may include a gas tank, a compressor, and a valve. The plasma may be generated from a portion of gas supplied from the gas supply GS to the process space 1h.

The showerhead 3, the outer ring 51, and the heating liner ring 53 will be further discussed below.

Referring to FIG. 2, the stage 7 may include an edge ring electrode EE, an edge ring ER, a chuck 71, and a cooling plate 73. The edge ring electrode EE may surround the stage 7. The edge ring ER may be disposed on the edge ring electrode EE.

The substrate W may be disposed on the chuck 71. The chuck 71 may rigidly place the substrate W on a certain position. The chuck 71 may include a chuck body 711, a plasma electrode 713, a chuck electrode 715, and a heater 717.

The chuck body 711 may have a cylindrical shape. The chuck body 711 may include or may be formed of a ceramic material, but the present inventive concepts are not limited thereto. The substrate W may be disposed on a top surface of the chuck body 711. The edge ring electrode EE may surround the chuck body 711.

The plasma electrode 713 may be positioned in the chuck body 711. The plasma electrode 713 may include or may be formed of aluminum (Al). The plasma electrode 713 may have a disk shape, but the present inventive concepts are not limited thereto. A RF power may be applied to the plasma electrode 713. For example, the RF power generator 4 may apply the RF power to the plasma electrode 713. The RF power applied to the plasma electrode 713 may control the plasma in the process space (see 1h of FIG. 1).

The chuck electrode 715 may be positioned in the chuck body 711. The chuck electrode 715 may be positioned higher than the plasma electrode 713. A DC power may be applied to the chuck electrode 715. For example, the DC power generator 2 may apply the DC power to the chuck electrode 715. The DC power applied to the chuck electrode 715 may rigidly place the substrate W on a certain position on the chuck body 711. For example, the DC power applied to the chuck electrode 715 may generate an electrostatic force to hold the substrate W placed on the stage 7 in place. The chuck electrode 715 may include aluminum (Al), but the present inventive concepts are not limited thereto.

The heater 717 may be positioned in the chuck body 711. The heater 717 may be positioned between the chuck electrode 715 and the plasma electrode 713. The heater 717 may include a hot wire. For example, the heater 717 may include a concentrically circular shaped hot wire. The heater 717 may radiate heat to the surrounding environment. Therefore, the chuck body 711 may have an increased temperature.

The cooling plate 73 may be positioned beneath the chuck 71. For example, the chuck 71 may be positioned on the cooling plate 73. The cooling plate 73 may provide a cooling hole 73h. Cooling water may flow in the cooling hole 73h. The cooling water in the cooling hole 73h may absorb heat from the cooling plate 73.

The edge ring electrode EE may surround the stage 7. The edge ring ER may be disposed on the edge ring electrode EE. The edge ring electrode EE may supply the edge ring ER with an alternating current (AC) power. The AC power may have a frequency of about 300 kHz to about 500 kHz. As the edge ring electrode EE supplies the edge ring ER with the AC power, it may be possible to control a density of the plasma on the edge ring ER and a thickness of a sheath region of the plasma formed on an upper surface the edge ring which is exposed to the process space 1h.

The edge ring ER may be disposed on the edge ring electrode EE. The edge ring ER may surround the chuck 71. A bottom surface of the edge ring ER may be located at a level lower than that of the substrate W. A top surface of the edge ring ER may be located at a level higher than that of the substrate W. The edge ring ER may include or may be formed of silicon (Si) or silicon carbide (SiC). However, the level of the top surface of the edge ring ER is not limited thereto. The edge ring ER will be further discussed in detail below.

Referring to FIG. 3, the showerhead 3, the outer ring 51, and the heating liner ring 53 may be provided. The showerhead 3 may be positioned in the process chamber 1. For example, the showerhead 3 may be positioned in the process space 1h. The showerhead 3 may be disposed upwardly spaced apart from the stage 7. For example, the showerhead 3 may be disposed above the stage 7. A gas supplied from the gas supply GS may be uniformly sprayed through the showerhead 3 into the process space 1h.

The outer ring 51 may surround the showerhead 3. For example, outside the showerhead 3 when viewed in a plan view, the outer ring 51 may surround the showerhead 3. The outer ring 51 may be in contact with the showerhead 3. The term “contact,” or “in contact with,” as used herein, refers to a direct connection (i.e., physical touching) unless the context indicates otherwise

The heating liner ring 53 may surround the outer ring 51. For example, outside the outer ring 51, the heating liner ring 53 may surround the outer ring 51. The heating liner ring 53 may support the outer ring 51. The heating liner ring 53 may include or may be formed of aluminum (Al) and yttrium oxide (Y2O3). For example, yttrium oxide (Y2O3) may be coated on aluminum (Al) to form the heating liner ring 53.

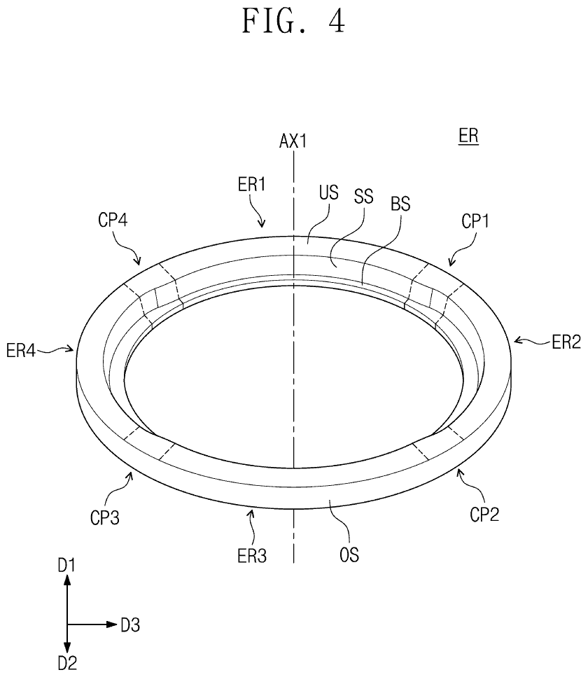

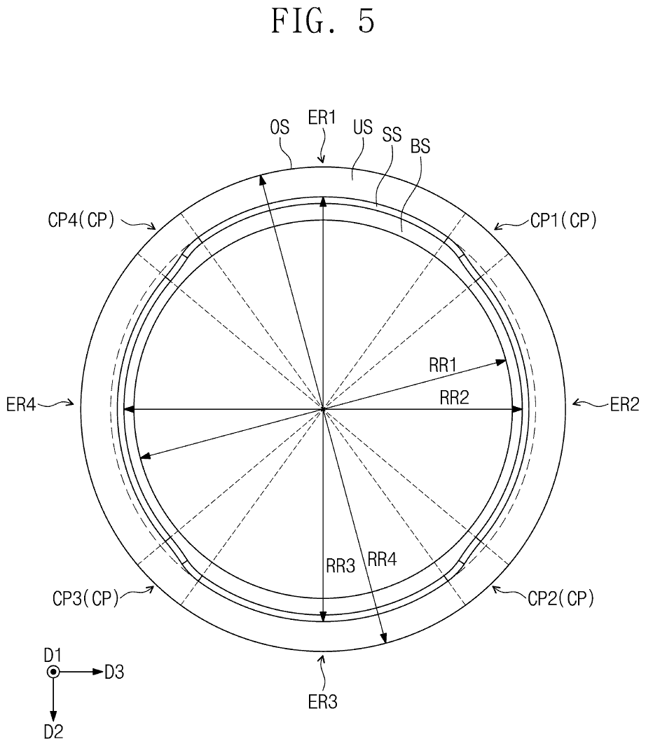

FIG. 4 illustrates a perspective view showing the edge ring ER according to some embodiments of the present inventive concepts. FIG. 5 illustrates a plan view showing the edge ring ER according to some embodiments of the present inventive concepts.

Referring to FIG. 4, the edge ring ER may include an edge ring region and a connection part CP. The edge ring region may include a first edge ring region ER1, a second edge ring region ER2, a third edge ring region ER3, and a fourth edge ring region ER4. The connection part CP may include a first connection part CP1, a second connection part CP2, a third connection part CP3, and a fourth connection part CP4. The first edge ring region ER1 and the second edge ring region ER2 may be connected through the first connection part CP1. The second edge ring region ER2 and the third edge ring region ER3 may be connected through the second connection part CP2. The third edge ring region ER3 and the fourth edge ring region ER4 may be connected through the third connection part CP3. The fourth edge ring region ER4 and the first edge ring region ER1 may be connected through the fourth connection part CP4.

The edge ring region may have an arc shape. For example, when viewed in a plan view, the edge ring ER may have a ring shape. The first to fourth edge ring regions ER1 to ER4 may be arranged on a same horizontal plane, and each of the first to fourth edge ring regions ER1 to ER4 may have an arc shape. The first to fourth edge ring regions ER1 to ER4 may have the same curvature center. However, the edge ring region may have an irregular curvature radius (i.e., different curvature radius). For example, the first edge ring region ER1 and the second edge ring region ER2 have the same curvature center (i.e., an imaginary circle fitting the first ring region ER1 and an imaginary circle fitting the second ring region ER2 are concentric), and the first edge ring region ER1 may have a first curvature radius, and the second edge ring region ER2 may have a second curvature radius different from the first curvature radius. The edge ring ER may have a first axis AX1 as a central axis. The first axis AX1 may pass through a center of the edge ring ER. In an embodiment, the center of the edge ring ER may correspond to the same curvature center of the first to fourth edge ring regions ER1 to ER4. The first edge ring region ER1 may have the same shape as that of the third edge ring region ER3. The second edge ring region ER2 may have the same shape as that of the fourth edge ring region ER4. In some embodiments, the first edge ring region ER1 may be different from the second edge ring region ER2 in shape. The present inventive concepts, however, are not limited thereto. In this description, a description of the first edge ring region ER1 may hold true for the third edge ring region ER3. A description of the second edge ring region ER2 may hold true for the fourth edge ring region ER4. The edge ring ER may have an outer lateral surface OS, an outer top surface US, an inner top surface BS, and an inclined surface SS. The outer top surface US may have a width greater than that of the inner top surface BS. For example, the outer top surface US may have a first radial width measured in a radial direction extending from the first axis AX1, and a second radial width measured in the radial direction. The first radial width may be greater than the second radial width. The outer top surface US may be located at a constant level. An outer top surface (see US1 of FIG. 7) of the first edge ring region ER1 may be located at a level which is the same as that of an outer top surface (see US2 of FIG. 10) of the second edge ring region ER2. The inner top surface BS may be located at a constant level. An inner top surface (see BS1 of FIG. 7) of the first edge ring region ER1 may be located at a level which is the same as that of an inner top surface (see BS2 of FIG. 10) of the second edge ring region ER2. The outer top surface US may be located at a level higher than that of the inner top surface BS. The outer top surface US may be parallel to the inner top surface BS.

The outer top surface US and the inner top surface BS may be connected through the inclined surface SS. For example, a width (see RR3 of FIG. 5) of an upper end of the inclined surface SS may indicate an inner diameter RR3 of the outer top surface US. However, the term “inner diameter” in this description may denote an inner width between opposite edge ring regions measured at where the upper end of the inclined surface SS and the outer top surface US. The inner diameter RR3 of the outer top surface US may mean twice a distance from the first axis AX1 to the upper end of the inclined surface SS. In an embodiment, the inner diameter RR3 may correspond to a distance between where a portion of the upper end of the inclined surface SS and the first edge ring region ER1 meet each other and where a portion of the upper end of the inclined surface SS and the third edge ring region ER3 opposite to the first edge ring region ER1. An inner diameter of the edge ring ER may not be constant. The upper end of the inclined surface SS may be located at a level which is the same as that of the outer top surface US. A width (see RR2 of FIG. 5) of a lower end of the inclined surface SS may indicate an outer diameter RR2 of the inner top surface BS. However, the term “outer diameter” in this description may denote an outer width between opposite edge ring regions measured at where the lower end of the inclined surface SS and the inner top surface BS. The outer diameter RR2 of the inner top surface BS may mean twice a distance from the first axis AX1 to the lower end of the inclined surface SS. An outer diameter may not be constant. The lower end of the inclined surface SS may be located at a level which is the same as that of the inner top surface BS.

The first edge ring region ER1, the second edge ring region ER2, the third edge ring region ER3, and the fourth edge ring region ER4 may have the same curvature center. The first axis AX1 may pass through a curvature center of the edge ring region. Referring to FIGS. 7 and 10, an irregular horizontal distance may be provided between the first axis AX1 and the inclined surface SS at a first level H1. For example, referring to FIG. 5, the width RR3 of the upper end of the inclined surface SS may not be constant. The width RR2 of the lower end of the inclined surface SS may not be constant. For example, a width (i.e., a distance) between first opposite portions of the lower end of the inclined surface SS may be different from a width (i.e., a distance) between second opposite portions of the lower end of the inclined surface SS. The first opposite portions may be in the first ring region ER1 and the third ring region ER3, respectively. The second opposite portions may be in the second ring region ER2 and the fourth ring region ER4, respectively. This will be discussed below.

Referring to FIG. 5, a plan view of the edge ring ER may be provided. The inner diameter RR3 of the outer top surface US may not be constant. The outer diameter RR2 of the inner top surface BS may not be constant. For example, an inner diameter RR3 of the outer top surface (see US1 of FIG. 7) of the first edge ring region ER1 may be different from an inner diameter RR3 of the outer top surface (see US2 of FIG. 10) of the second edge ring region ER2. The inner diameter RR3 of the outer top surface US1 of the first edge ring region ER1 may be greater than the inner diameter RR3 of an outer top surface US2 of the second edge ring region ER2. An outer diameter RR2 of the inner top surface BS1 of the first edge ring region ER1 may be different from an outer diameter RR2 of the inner top surface BS2 of the second edge ring region ER2. For example, the outer diameter RR2 of the inner top surface BS1 of the first edge ring region ER1 may be greater than the outer diameter RR2 of the inner top surface BS2 of the second edge ring region ER2. The first edge ring region ER1 and the second edge ring region ER2 will be discussed below. The first connection part CP1 may connect the first edge ring region ER1 to the second edge ring region ER2. The first connection part CP1 may have a shape which is the same as that of the third connection part CP3. The second connection part CP2 may have a shape which is the same as that of the fourth connection part CP4. The shape of the first connection part CP1 may be mirror symmetric with that of the second connection part CP2. The shape of the first connection part CP1 will be discussed below. However, the shape of the connection part CP is not limited thereto. The first connection part CP1, the second connection part CP2, the third connection part CP3, and the fourth connection part CP4 may have different shapes from each other. The outer top surface US may have a constant outer diameter RR4. For example, the outer lateral surface OS may have a circular shape, and the radius of the outer lateral surface OS may correspond to the constant outer diameter RR4. In an embodiment, the outer top surface US may have an outer boundary defining an outermost boundary of the edge ring ER when viewed in a plan view. The outer boundary of the outer top surface US may be a circle having the constant outer diameter RR4. However, the shape of the outer lateral surface OS is not limited thereto. The outer lateral surface OS may be bent along the upper end of the inclined surface SS. The inner top surface BS may have a constant inner diameter RR1. In an embodiment, an inner boundary of the inner top surface BS may have a circular shape and define a hollow region of the edge ring ER when viewed in a plan view. The circular shape of the outer lateral surface OS and the circular shape of the inner boundary of the inner top surface BS may be concentric at the first axis AX1 of the edge ring ER. The inner diameter RR1 of the inner top surface BS may range from about 295 mm to about 350 mm.

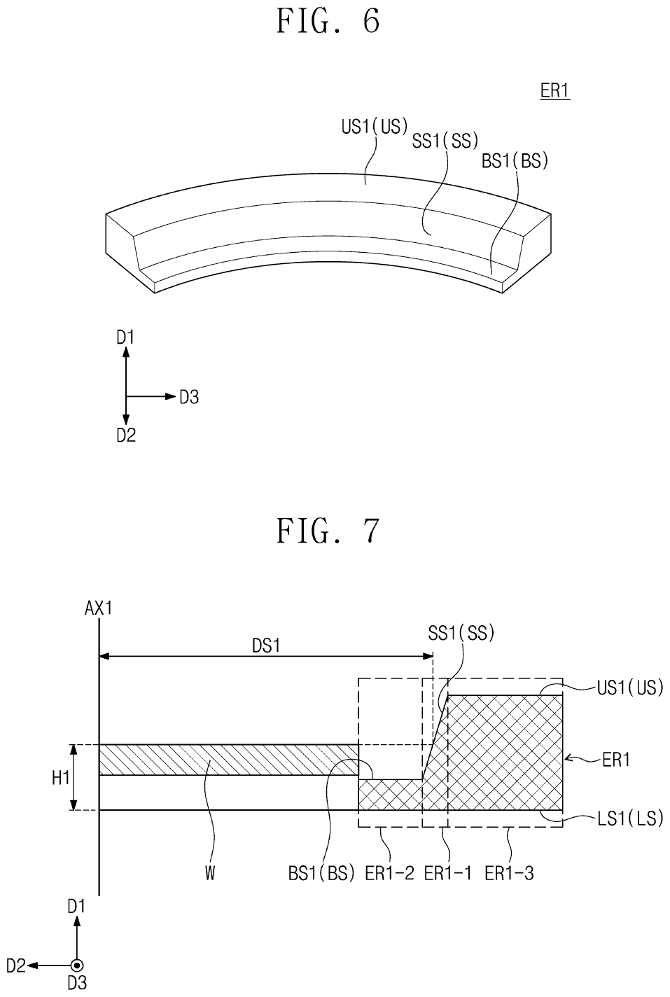

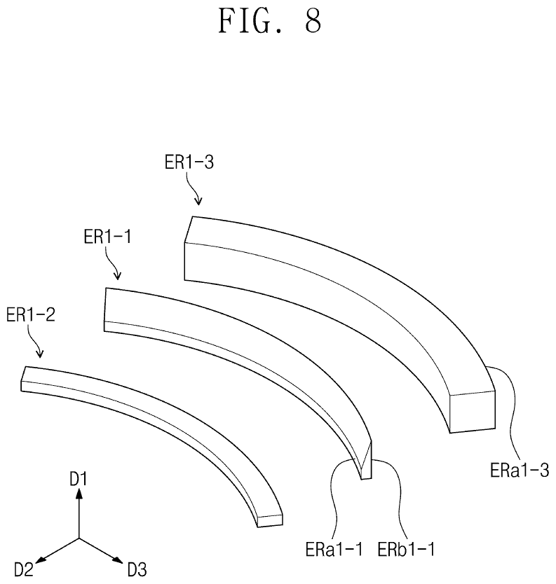

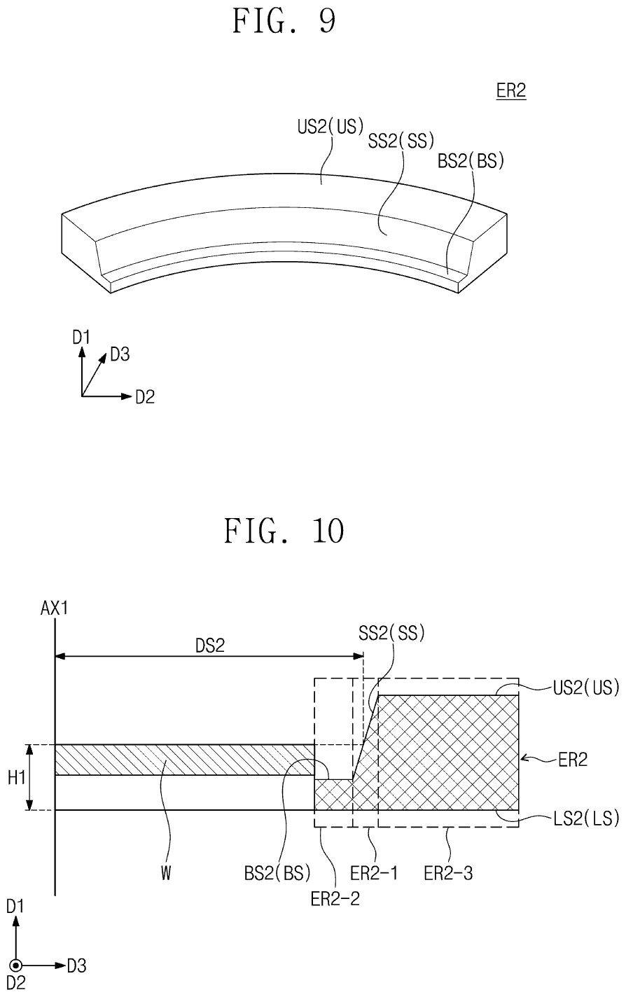

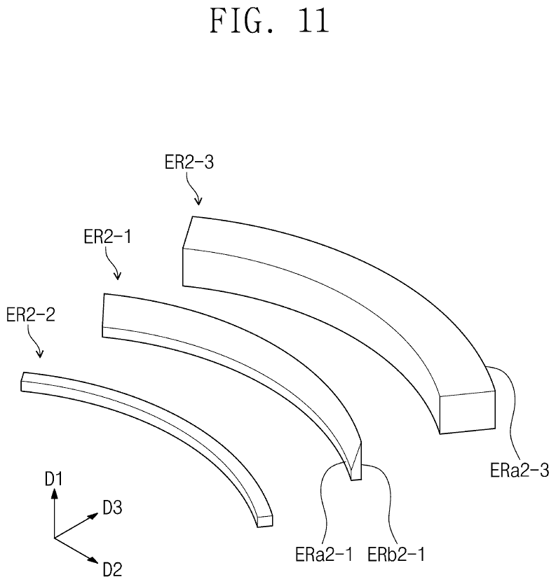

FIG. 6 illustrates a perspective view showing the first edge ring region ER1 according to some embodiments of the present inventive concepts. FIG. 7 illustrates a cross-sectional view showing the first edge ring region ER1 according to some embodiments of the present inventive concepts. FIG. 8 illustrates an exploded perspective view showing the first edge ring region ER1 according to some embodiments of the present inventive concepts. FIG. 9 illustrates a perspective view showing the second edge ring region ER2 according to some embodiments of the present inventive concepts. FIG. 10 illustrates a cross-sectional view showing the second edge ring region ER2 according to some embodiments of the present inventive concepts. FIG. 11 illustrates an exploded perspective view showing the second edge ring region ER2 according to some embodiments of the present inventive concepts.

Referring to FIGS. 6 and 7, the first edge ring region ER1 may have a first outer top surface US1, a first inner top surface BS1, and a first inclined surface SS1. The first outer top surface US1 may be included in the outer top surface US. The first inner top surface BS1 may be included in the inner top surface BS. The first inclined surface SS1 may be included in the inclined surface SS. Referring to FIG. 7, a cross-section may be obtained when the first edge ring region ER1 is cut by a plane including the first axis AX1. The cross-section of the first edge ring region ER1 may be constant. Referring to FIGS. 5 and 7, the first outer top surface US1 may have a constant inner diameter. The inner diameter of the first outer top surface US1 may mean a twice a distance from the first axis AX1 to an upper end of the first inclined surface SS1. The first inner top surface BS1 may have a constant outer diameter. The outer diameter of the first inner top surface BS1 may mean a twice a distance from the first axis AX1 to a lower end of the first inclined surface SS1. Referring to FIGS. 7 and 8, the first edge ring region ER1 may be divided into three regions. The first edge ring region ER1 may include a 1-1st edge ring region ER1-1 having the first inclined surface SS1. The first edge ring region ER1 may have a 1-2nd edge ring region ER1-2 having the first inner top surface BS1. The first edge ring region ER1 may include a 1-3rd edge ring region ER1-3 having the first outer top surface US1. An inner surface ERa1-1 of the 1-1st edge ring region ER1-1 may be connected to the 1-2nd edge ring region ER1-2.

Referring to FIGS. 7 and 8, an outer surface ERb1-1 of the 1-1st edge ring region ER1-1 may be connected to the 1-3rd edge ring region ER1-3. A first horizontal distance DS1 may refer to a distance from the first axis AX1 to the first inclined surface SS1. The first horizontal distance DS1 may mean a horizontal distance between the first axis AX1 and the first inclined surface SS1 at the first level H1. The first level H1 may be lower than a level of the upper end of the first inclined surface SS1. The first level H1 may be higher than a level of the lower end of the first inclined surface SS1. The first level H1 may indicate a level of a top surface of the substrate W.

Referring to FIGS. 9 and 10, the second edge ring region ER2 may have a second outer top surface US2, a second inner top surface BS2, and a second inclined surface SS2. The second outer top surface US2 may be included in the outer top surface US. The second inner top surface BS2 may be included in the inner top surface BS. The second inclined surface SS2 may be included in the inclined surface SS. Referring to FIG. 10, a cross-section may be obtained when the second edge ring region ER2 is cut by a plane including the first axis AX1. The cross-section of the second edge ring region ER2 may be constant. The second outer top surface US2 may have a constant inner diameter. The inner diameter of the second outer top surface US2 may mean a twice a distance from the first axis AX1 to an upper end of the second inclined surface SS2. The second inner top surface BS2 may have a constant outer diameter. The outer diameter of the second inner top surface BS2 may mean a twice a distance from the first axis AX1 to a lower end of the second inclined surface SS2. Referring to FIGS. 9 and 10, the second edge ring region ER2 may be divided into three regions. The second edge ring region ER2 may include a 2-1st edge ring region ER2-1 having the second inclined surface SS2. The second edge ring region ER2 may have a 2-2nd edge ring region ER2-2 having the second inner top surface BS2. The second edge ring region ER2 may include a 2-3rd edge ring region ER2-3 having the second outer top surface US2. An inner surface Era2-1 of the 2-1st edge ring region ER2-1 may be connected to the 2-2nd edge ring region ER2-2. An outer surface ERb2-2 of the 2-1st edge ring region ER2-1 may be connected to the 2-3rd edge ring region ER2-3. A thickness of the 2-2nd edge ring region ER2-2 may be the same as that of the 1-2nd edge ring region ER1-2. A thickness of the 2-3rd edge ring region ER2-3 may be the same as that of the 1-3rd edge ring region ER1-3. In an embodiment, the thicknesses may be measured in a vertical direction extending along the first axis AX1. A second horizontal distance DS2 may refer to a distance from the first axis AX1 to the second inclined surface SS2. The second horizontal distance DS2 may mean a horizontal distance between the first axis AX1 and the second inclined surface SS2 at the first level H1. Referring to FIGS. 8 and 11, an outer surface of the 1-3rd edge ring region ER1-3 may have a curvature radius which is the same as that of an outer surface of the 2-3rd edge ring region ER2-3. For example, when the outer surface of the 1-3rd edge ring region ER1-3 may be fitted into a first imaginary circle when viewed in a plan view, a radius of the first imaginary circle corresponds to the curvature radius of the 1-3rd edge ring region ER1-3. Similarly, when the outer surface of the 2-3rd edge ring region ER2-3 may be fitted into a second imaginary circle when viewed in a plan view, a radius of the second imaginary circle corresponds to the curvature radius of the 2-3rd edge ring region ER2-3. The first imaginary circle and the second imaginary circle may be the same as each other, and thus the curvature radius of the outer surface of the 1-3rd edge ring region ER1-3 is the same as the curvature radius of the outer surface of the 2-3rd edge ring region ER2-3.

Referring to FIGS. 7 and 10, the first horizontal distance DS1 and the second horizontal distance DS2 may be different from each other. For example, the first horizontal distance DS1 may be greater than the second horizontal distance DS2. A ratio of a difference between the first and second horizontal distances DS1 and DS2 to the second horizontal distance DS2 may be equal to or less than about 1%. A width of a bottom surface LS1 of the first edge ring region ER1 may be the same as a width of a bottom surface LS2 of the second edge ring region ER2. A width of the outer top surface US, a width of the inner top surface BS, and a slope of the inclined surface SS may be adjusted to change a cross-sectional shape of the first edge ring region ER1 and a cross-sectional shape of the second edge ring region ER2. A slope of the first inclined surface SS1 may be the same as that of the second inclined surface SS2, but the present inventive concepts are not limited thereto. The cross-sectional shapes of the first and second edge ring regions ER1 and ER2 may be changed within a range in which the first horizontal distance DS1 is greater than the second horizontal distance DS2. For example, a width of the second outer top surface US2 may be greater than that of the first outer top surface US1. A width of the first inner top surface BS1 may be greater than that of the second inner top surface BS2. A width of the 1-2nd edge ring region ER1-2 may be greater than that of the 2-2nd edge ring region ER2-2. The present inventive concepts, however, are not limited thereto. A relationship between the width of the first outer top surface US1 and the width of the second outer top surface US2 may be changed depending on the slope of the first inclined surface SS1 and the slope of the second inclined surface SS2. For example, in a case where the width of the first inner top surface BS1 is the same as that of the second inner top surface BS2, a reduction in the slope of the first inclined surface SS1 may cause the first horizontal distance DS1 to be greater than the second horizontal distance DS2. When the width of the first inner top surface BS1 is increased, the first horizontal distance DS1 may be greater than the second horizontal distance DS2 by making the slope of the first inclined surface SS1 greater than that of the second inclined surface SS2.

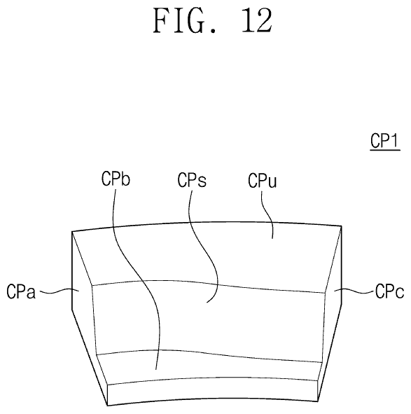

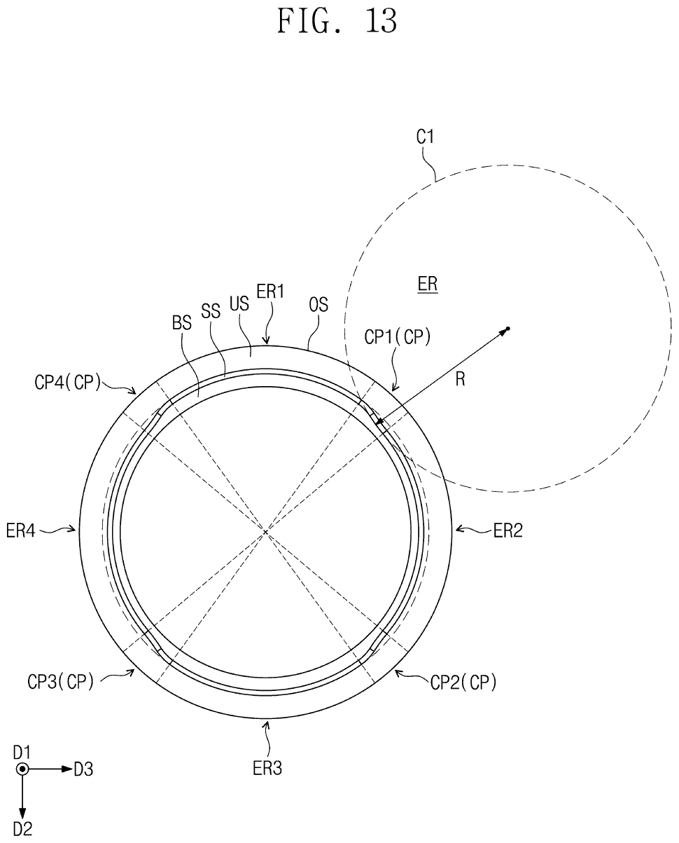

FIG. 12 illustrates a perspective view showing the first connection part CP1 according to some embodiments of the present inventive concepts. FIG. 13 illustrates a plan view showing the edge ring ER according to some embodiments of the present inventive concepts.

Referring to FIGS. 12 and 13, the first connection part CP1 may be provided. A cross-section obtained when the first connection part CP1 is cut by a plane including the first axis AX1 may not be constant. The first connection part CP1 may have a first cross-section CPa which is the same as a cross-section of the first edge ring region ER1. The first connection part CP1 may have a second cross-section CPc which is the same as a cross-section of the second edge ring region ER2. The first connection part CP1 may have a first connection outer top surface CPu, a first connection inner top surface CPb, and a first connection inclined surface CPs. An upper end of the first connection inclined surface CPs may connect an upper end of the first inclined surface SS1 to an upper end of the second inclined surface SS2. A lower end of the first connection inclined surface CPs may connect a lower end of the first inclined surface SS1 to a lower end of the second inclined surface SS2. The first connection outer top surface CPu and the first connection inner top surface CPb may each have an irregular width (i.e., different widths). The first connection part CP1 may have a curved surface to connect the first inclined surface SS1 to the second inclined surface SS2. The first connection part CP1 may have a first imaginary circle C1 including a portion of the upper end of the first connection inclined surface CPs. The first circle C1 may include a portion of the lower end of the first connection inclined surface CPs. The first circle C1 may have a radius R of equal to or less than about 170 mm. For example, the first connection inclined surface CPs may have a curved surface whose curvature radius is equal to or less than about 170 mm.

According to an edge ring and a substrate processing apparatus including the same in accordance with some embodiments of the present inventive concepts, an edge ring may be provided which has an inclined surface whose upper and lower ends have their irregular widths. The width of each of the upper and lower ends of the inclined surface may be changed by adjusting an inner top surface, an outer top surface, and a slope of the inclined surface. The change in shape of the edge ring may variously change plasma on the edge ring. The change in shape of the edge ring may control plasma on an edge of a substrate.

According to an edge ring and a substrate processing apparatus including the same in accordance with some embodiments of the present inventive concepts, there may be an irregular horizontal distance from a first axis to an inclined surface at a level at which a top surface of a substrate is located. A first level may refer to the level of the top surface of the substrate. The variation in the horizontal distance from the first axis to the inclined surface at the first level may cause a sheath region to have a slope that is changed from positive to negative or vice versa. The slope of the sheath region may be controlled to adjust a substrate etching amount due to plasma.

According to an edge ring and a substrate processing apparatus including the same in accordance with some embodiments of the present inventive concepts, it may be possible to reduce etching asymmetry caused by patterns formed on a substrate. A substrate etching may be more etched in a pattern direction. For example, when a pattern is horizontally formed on the substrate, an etching may be performed more in a horizontal direction. A semiconductor chip disposed laterally across a center of the substrate may be etched more than a semiconductor chip disposed vertically across the center of the substrate. A distance from a first axis to an inclined at a first level may be adjusted to reduce a difference in etching amount depending on position of the semiconductor chip.

According to an edge ring and a substrate processing apparatus of the present inventive concepts, it may be possible to increase a region where plasma is uniformly present.

According to an edge ring and a substrate processing apparatus of the present inventive concepts, a concentration of plasma may be controlled to increase an etching rate of an edge region of a substrate.

According to an edge ring and a substrate processing apparatus of the present inventive concepts, a slope of a plasma sheath region may be reduced to increase an etching rate of an edge region of a substrate.

According to an edge ring and a substrate processing apparatus of the present inventive concepts, it may be possible to reduce the degree of asymmetry in etching amount in accordance with a pattern direction of a substrate.

According to an edge ring and a substrate processing apparatus of the present inventive concepts, it may be possible to increase a region where plasma is uniformly present.

Effects of the present inventive concepts are not limited to the mentioned above, other effects which have not been mentioned above will be clearly understood to those skilled in the art from the following description.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. An edge ring comprising:
a first edge ring region that has a first arc shape having a first curvature center; and
a second edge ring region connected to the first edge ring region and having a second arc shape having a second curvature center,
wherein the first edge ring region and the second edge ring region are arranged on a horizontal plane,
wherein the first curvature center and the second curvature center are the same as each other,
wherein a first vertical axis is perpendicular to the horizontal plane and passes through the second curvature center of the second edge ring region and the first curvature center of the first edge ring region,
wherein the first edge ring region includes a 1-1st edge ring region having a first inclined surface intersecting the horizontal plane,
wherein the second edge ring region includes a 2-1st edge ring region having a second inclined surface intersecting the horizontal plane, and
wherein a first horizontal distance from the first vertical axis to the first inclined surface is greater than a second horizontal distance from the first vertical axis to the second inclined surface.

2. The edge ring of claim 1,
wherein the first edge ring region and the second edge ring region include silicon (Si) or silicon carbide (SiC).

3. The edge ring of claim 1,
wherein a first slope, relative to the horizontal plane, of the first inclined surface is less than a second slope, relative to the horizontal plane, of the second inclined surface.

4. The edge ring of claim 1,
wherein the first edge ring region includes:
a 1-2nd edge ring region connected to an inner surface of the 1-1st edge ring region; and
a 1-3rd edge ring region connected to an outer surface of the 1-1st edge ring region, and
wherein the second edge ring region includes:
a 2-2nd edge ring region connected to an inner surface of the 2-1st edge ring region; and
a 2-3rd edge ring region connected to an outer surface of the 2-1st edge ring region.

5. The edge ring of claim 4,
wherein a width, in a radial direction extending from the first vertical axis, of an upper surface of the 1-2nd edge ring region is greater than a width, in the radial direction from the first vertical axis, of an upper surface of the 2-2nd edge ring region.

6. The edge ring of claim 5,
wherein a slope, relative to the horizontal plane, of the first inclined surface is the same as a slope, relative to the horizontal plane, of the second inclined surface.

7. The edge ring of claim 4,
wherein a curvature radius of an outer surface of the 1-3rd edge ring region is the same as a curvature radius of an outer surface of the 2-3rd edge ring region.

8. The edge ring of claim 4,
wherein a thickness, in a vertical direction, of the 1-3rd edge ring region is the same as a thickness, in the vertical direction, of the 2-3rd edge ring region,
wherein a thickness, in the vertical direction, of the 1-2nd edge ring region is the same as a thickness, in the vertical direction, of the 2-2nd edge ring region, and
wherein the vertical direction is perpendicular to the horizontal plane, and the first vertical axis extends in the vertical direction.

9. The edge ring of claim 1, further comprising:
a first connection part connecting the first inclined surface to the second inclined surface,
wherein the first connection part has a curved surface intersecting the horizontal plane and having a curvature radius which is equal to or less than about 170 mm.

10. The edge ring of claim 1,
wherein a ratio of a difference between the first and second horizontal distances to the second horizontal distance is equal to or less than about 1%.

11. An edge ring comprising:
an inner top surface parallel to a horizontal plane;
an outer top surface that is parallel to the horizontal plane and surrounds the inner top surface; and
an inclined surface that intersects the horizontal plane and connects the inner top surface to the outer top surface,
wherein the outer top surface is at a level higher than a level of the inner top surface in a vertical direction perpendicular to the horizontal plane,
wherein a lower end of the inclined surface is at a level which is the same as the level of the inner top surface in the vertical direction,
wherein an upper end of the inclined surface is at a level which is the same as the level of the outer top surface in the vertical direction,
wherein a first horizontal distance between a first portion of the inclined surface and a vertical axis of the edge ring at a first level in the vertical direction is different from a second horizontal distance between a second portion of the inclined surface and the vertical axis of the edge ring at the first level, and
wherein the vertical axis extends in the vertical direction and passes a center of the edge ring.

12. The edge ring of claim 11,
wherein the inner top surface has an inner boundary defining a hollow region of the edge ring when viewed in a plan view, and
wherein the inner boundary of the inner top surface is a circle having a constant inner diameter.

13. The edge ring of claim 11,
wherein the outer top surface has an outer boundary defining an outermost boundary of the edge ring when viewed in a plan view, and
wherein the outer boundary of the outer top surface is a circle having a constant outer diameter.

14. The edge ring of claim 11, further comprising:
a curved surface connecting the first portion of the inclined surface to the second portion of the inclined surface,
wherein a horizontal distance between the curved surface to the vertical axis of the edge ring at the first level has an increasing distance from the first horizontal distance to the second horizontal distance.

15. The edge ring of claim 11,
wherein a width, in a radial direction extending from the vertical axis, of the outer top surface is greater than a width, in the radial direction extending from the vertical axis, of the inner top surface.

16. The edge ring of claim 11,
wherein a width between first opposite portions of the lower end of the inclined surface is different from a width between second opposite portions of the lower end of the inclined surface.

17. The edge ring of claim 12,
wherein the constant inner diameter of the inner top surface has a value in a range from about 295 mm to about 350 mm.

18. A edge ring comprising:
a first edge ring region that has a first arc shape having a first curvature center; and
a second edge ring region connected to the first edge ring region and having a second arc shape having a second curvature center,
wherein the first curvature center and the second curvature center are the same as each other,
wherein a first vertical axis is perpendicular to an upper surface of the chuck and passes through the second curvature center of the second edge ring region and the first curvature center of the first edge ring region,
wherein the upper surface of the chuck corresponds to the upper surface of the stage,
wherein the first edge ring region and the second edge ring region have a first inclined surface intersecting a horizontal plane parallel to the upper surface of the chuck and a second inclined surface intersecting the horizontal plane, respectively,
wherein the slope of the first inclined surface is different from the slope of the second inclined surface, and
wherein a first horizontal distance from the first vertical axis to the first inclined surface at a first level in the vertical direction is greater than a second horizontal distance from the first vertical axis to the second inclined surface at the first level.

19. The edge ring of claim 18,
wherein a slope, relative to the horizontal plane, of the first inclined surface is greater than a slope, relative to the horizontal plane, of the second inclined surface.

20. The edge ring of claim 18, further comprising:
a first connection part connecting the first inclined surface to the second inclined surface,
wherein the first connection part has a curved surface intersecting the horizontal plane and having a curvature radius which is equal to or less than about 170 mm.
